(19) United States
(12) Patent Application Publication
(10) Pub. No.: US 2013/0008510 A1
(43) Pub. Date: Jan. 10, 2013

(54) PHOTOELECTRIC CONVERSION ELEMENT, PHOTOSENSOR, AND SOLAR CELL

(75) Inventors: Shin Nakamura, Tokyo (JP); Katsumi Maeda, Tokyo (JP); Kentaro Nakahara, Tokyo (JP); Masahiro Suguro, Tokyo (JP)

(73) Assignee: NEC Corporation, Tokyo (JP)

(21) Appl. No.: 13/636,609

(22) PCT Filed: Mar. 22, 2011
(86) PCT No.: PCT/JP2011/001662

§ 371 Date: Sep. 21, 2012

(30) Foreign Application Priority Data
Mar. 24, 2010 (JP) 2010 067282

(51) Int. Cl. H01L 51/44; H01L 51/46

(52) U.S. Cl. 136/263; 257/40; 257/E51.015; 257/E51.026

(57) ABSTRACT

An object of the present invention is to provide a photoelectric conversion element having excellent photoelectric conversion efficiency and durability. To achieve the object, the present invention provides a photoelectric conversion element including a semiconductor electrode (70) that has a porous semiconductor layer (30) onto which a dye (40) is adsorbed, a counter electrode (60) that is provided so as to face the semiconductor layer (30) of the semiconductor electrode (70), and an electrolyte (50) that contains a radical compound having an average molecular weight of 200 or more and is positioned between the semiconductor electrode (70) and the counter electrode (60).

### TECHNICAL FIELD

The present invention relates to a photoelectric conversion element, a photosensor, and a solar cell.

### BACKGROUND ART

There are several types of photoelectric conversion elements or solar cells converting light energy into electrical energy, but most of them are a diode type using junction of silicon semiconductors or gallium arsenide semiconductors. To reduce costs of these solar cells has become one of the problems to be solved for distributing the solar cells for household power. The dye-sensitized wet type solar cell (Nature 353 (1991) 737) invented in 1991 by Grätzel et al. operates by a photoelectric conversion mechanism different from that of solar cells of the silicon semiconductor, and a photoelectric conversion efficiency thereof is relatively high, such as about 10%. Accordingly, this solar cell is expected to be an element that will be likely to replace silicon-based solar cells in the future.

The basic structure of the dye-sensitized wet type solar cell (dye-sensitized solar cell) is constituted such that two electrodes including an electrode which is formed on a transparent substrate and formed of a transparent conductive film and a counter electrode to which platinum or the like is vapor-deposited are pasted on each other. Generally, as a base of the transparent substrate and the counter electrode, glass having a thickness of about 1 mm is used. On the transparent conductive film, an oxide semiconductor layer is formed, and a dye is adsorbed onto the surface of the oxide semiconductor layer. In addition, between the two electrodes, an electrolyte solution having a redox pair for transporting holes generated from the dye is injected.

As the dye, a sensitizing dye such as a ruthenium (Ru) complex that can efficiently absorb sunlight is used. When the solar cell is irradiated with light, the sensitizing dye is excited, and electrons are injected to the oxide semiconductor layer. The electrons injected into the oxide semiconductor layer reach the counter electrode through an external circuit.

On the other hand, the holes formed simultaneously with the electrons from the dye are transported to the counter electrode through a redox reaction of redox species included in the electrolyte solution, and cause annihilation with the electrons that have reached the counter electrode through an external circuit. By this principle, the dye-sensitized solar cell can generate current. As the electrolyte solution necessary for giving and receiving electrons, an iodine-based electrolyte including an organic solvent is used in general.

The dye-sensitized wet type solar cell of the above principle was studied actively before the invention of Grätzel et al. However, a photoelectric conversion efficiency thereof was generally as low as not more than 1%, and this is because the probability of capturing light in the portion of the sensitizing dye is low. Accordingly, the above solar cell was considered to be a technique less likely to be commercialized.

However, Grätzel et al. imparted porosity to the oxide semiconductor layer to obtain a titanium oxide (TiO₂) electrode having a large surface area, thereby solving the above problems by using this electrode. According to this constitution, since the amount of a dye adsorbed onto the surface of the oxide semiconductor layer increases, it is possible to increase the probability of capturing light in the sensitizing dye. Due to this amelioration, a photoelectric conversion efficiency of about 10% has been realized in the dye-sensitized solar cell.

In the above technique, in order to improve the photoelectric conversion efficiency, the specific surface area onto which a dye can be adsorbed is enlarged, whereby a light absorption efficiency of a dye is increased. At this time, in order to enlarge the specific surface area, it is desirable to reduce a particle size of titanium oxide forming the oxide semiconductor layer. However, if the particle size of titanium oxide is reduced to a nanometer size, the specific surface area is enlarged, but at the same time, the oxide semiconductor layer obtains a property of transmitting sunlight. With the property of transmitting sunlight, the light not absorbed by the dye passes through the oxide semiconductor layer and cannot be used for power generation.

In order to solve the problem and improve the photoelectric conversion efficiency, a technique of forming a light scattering layer for scattering light to a surface opposite to a light-incidence surface of the oxide semiconductor layer so as to return the light having passed through the oxide semiconductor layer to the oxide semiconductor layer again, a technique of introducing a scatterer into the semiconductor layer, or the like is used. The light scattering layer or the scatterer includes oxide particles such as titanium oxide having a particle size of several hundred nanometers, and reflects and scatters light to improve the rate of utilization of light in the oxide semiconductor. These techniques have realized a higher photoelectric conversion efficiency.

The dye-sensitized wet type solar cell invented by Grätzel et al. has a relatively high photoelectric conversion efficiency of about 10%. However, using an electrolyte including iodine, this solar cell is not easily sealed, which leads to a problem of durability.

In this respect, Grätzel et al. demonstrated that by using a redox reaction of a 2,2,6,6-tetramethylpiperidine-N-oxyl (TEMPO) radical in an electrolyte not including iodine, a solar cell with a high efficiency can be realized (Non-Patent Document 1).

The basic idea of applying the redox reaction of a radical compound to a photoelectric conversion element is disclosed in Patent Document 1. In the invention, a semiconductor electrode contacts a radical compound to give and receive charge. This constitution has a problem in that charge from the radical compound easily recombines with the semiconductor electrode.

In order to solve the problem, Patent Document 2 discloses a technique of forming an electron-permeable insulating layer on the surface of a semiconductor layer of a semiconductor electrode, and providing a radical compound on the insulating layer. Patent Document 2 discloses that according to this technique, since the radical compound and the semiconductor layer do not come into direct contact with each other, the recombination of charge can be inhibited, and the efficiency of the photoelectric conversion element can be improved.

In addition, Patent Document 2 discloses an organic substance (tertiary-butylpyridine or the like) having an unshared electron pair, as an example of a specific substance for the electron-permeable insulating layer. Patent Document 2 also discloses that the electron-permeable insulating layer can contain a dye, and that the molecular weight of the radical compound is 1000 or more.

### RELATED DOCUMENTS

### Patent Documents

[Patent Document 1] Japanese Laid-open Patent Publication No. 2003-100360

[Patent Document 2] Japanese Laid-open Patent Publication No. 2009-21212

### Non-Patent Document

[Non-Patent Document] Z. Zhang, P. Chen, T. N. Murakami, S. M. Zakeeruddin, M. Grätzel, Adv. Funct. Mater. 2008, 18, 341.

### DISCLOSURE OF THE INVENTION

As described above, the photoelectric conversion element using an electrolyte including iodine is not easily sealed, which leads to a problem of durability. In addition, a photoelectric conversion element using an electrolyte including a radical compound instead of iodine has a problem in that the photoelectric conversion efficiency is decreased due to the recombination of charge caused on the semiconductor layer by the radical compound. Moreover, in the case of the technique disclosed in Patent Document 2 that includes a unit for solving the problem, the following problem arises.

If an additive such as tertiary-butylpyridine is introduced as in the technique disclosed in Patent Document 2, since the additive interacts with a dye, a phenomenon in which the current value of a closed circuit itself is decreased is observed. In addition, if an organic dye or the like is used, the organic dye leaves the semiconductor surface, so efficiency is decreased in some cases. Furthermore, in order to be involved with the redox reaction of the radical compound, the electrons or holes generated from the semiconductor layer by light irradiation need to reach the radical compound via the insulating layer constituted with a material having electrical insulating properties. That is, the insulating layer is placed in the middle of the travelling path of a carrier. In the technique disclosed in Patent Document 2, the film thickness of the insulating layer is reduced so as to impart electron permeability to the insulating layer. However, electric resistance resulting from the insulating layer is not prevented, and photocurrent is decreased, whereby the photoelectric conversion efficiency is reduced.

In this respect, an object of the present invention is to provide a photoelectric conversion element that has excellent photoelectric conversion efficiency and durability.

According to the present invention, there is provided a photoelectric conversion element including a semiconductor electrode that has a porous semiconductor layer onto which a dye is adsorbed, a counter electrode that is provided so as to face the semiconductor layer of the semiconductor electrode, and an electrolyte that contains a radical compound having an average molecular weight of 200 or more and is positioned between the semiconductor electrode and the counter electrode.

In order to inhibit the recombination of charge caused on the semiconductor layer by the radical compound, exchange of electrons caused between the semiconductor layer that is exposed to gaps in the dye adsorbed onto the semiconductor layer and the radical compound in the electrolyte (charge transport layer) may be inhibited. That is, a physical structure that may inhibit the semiconductor layer and the radical compound from coming into contact with each other through a gap of the dye may be realized.

In a state where the dye is sufficiently adsorbed, the size of the gaps where the dye is not adsorbed is considered to be approximately smaller than the projected area of the dye adsorbed.

That is, if the radical compound is larger than the gaps with such a size, the radical compound fails to enter the gaps in the dye, and consequently, contact between the semiconductor layer and the radical compound may be inhibited.

By experience, the present inventors found that when a dye which is generally used for a photoelectric conversion element is used, by setting the average molecular weight of the radical compound to 200 or more, improvement of photoelectric conversion efficiency is realized. It is considered that this is because if the average molecular weight of the radical compound is set to 200 or more, the radical compound is inhibited from entering the gaps in the dye, and consequently, the recombination of charge caused on the semiconductor layer by the radical compound may be inhibited.

In the above respect, the larger the average molecular weight of the radical compound, the more preferable. However, if the average molecular weight of the radical compound is too large, the photoelectric conversion efficiency is reduced due to other factors.

That is, since the semiconductor layer is configured as a porous layer so as to enlarge the area onto which the dye is adsorbed, the dye is in a state of being adsorbed onto the inner wall of the pores. It is preferable that the size of the pores be small in view of enlarging the area onto which the dye is adsorbed, and for example, the size is designed to be a size of nanometers.

Accordingly, if the average molecular weight of the radical compound is too large, the radical compound does not enter the pores of the semiconductor layer, and the efficiency of contact between the radical compound and the dye is reduced. As a result, the photoelectric conversion efficiency is reduced.

By experience, the present inventors found that when a porous semiconductor layer which is generally used for a photoelectric conversion element is used, by setting the average molecular weight of the radical compound to less than 1000, improvement of photoelectric conversion efficiency is realized. It is considered that this is because if the average molecular weight of the radical compound is set to less than 1000, this makes it easy for the radical compound to enter the pores of the semiconductor layer, and consequently, the efficiency of contact between the radical compound and the dye is improved.

In addition, according to the present invention, since an electrolyte including iodine is not used, it is possible to realize excellent durability.

An object of the present invention is to provide a photoelectric conversion element that has excellent photoelectric conversion efficiency and durability.

### BRIEF DESCRIPTION OF THE DRAWINGS

The above object and other objects, characteristics, and advantages are further clarified by the following preferable embodiments and the following drawings appended thereto.

FIG. 1 schematically shows an example of the structure of a photoelectric conversion element of the present embodiment.

FIG. 2 shows the performance of the photoelectric conversion element of the present embodiment.

### DESCRIPTION OF EMBODIMENTS

The embodiments of the present invention will be described in detail with reference to drawings. All of the following structural views schematically show the embodiments of the present invention. Unless otherwise specified, the ratio between the constitutional elements in the drawings does not specify dimensions of the structure according to the present invention.

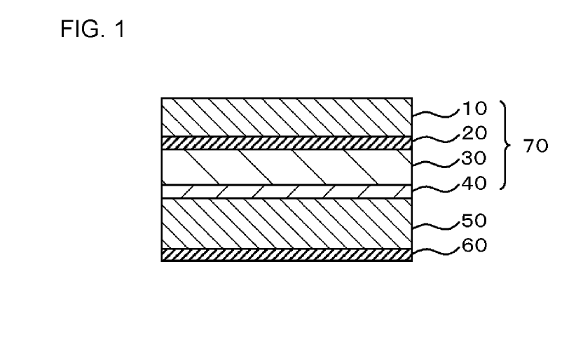

FIG. 1 schematically shows an example of the structure of the photoelectric conversion element of the present embodiment. As shown in the drawing, the photoelectric conversion element of the present embodiment includes a semiconductor electrode 70, a counter electrode 60, and an electrolyte 50 interposed between both the electrodes.

<Semiconductor Electrode 70>

The semiconductor electrode 70 includes a light transmissive substrate 10, a transparent conductive film 20 formed on this substrate, a semiconductor layer 30 formed on this film, and a dye 40 adsorbed onto the semiconductor layer 30.

<Light Transmissive Substrate 10>

In the present embodiment, the constitution of the light transmissive substrate 10 is not particularly limited, and various constitutions based on the technique in the related art can be employed. For example, the light transmissive substrate 10 may be a substrate constituted with an insulating material such as a glass substrate or a plastic substrate. When a glass substrate, a plastic substrate, or the like is used, a transparent conductive film is formed on the light transmissive substrate 10. In addition, the light transmissive substrate 10 may be a transparent substrate constituted with a conductive material.

<Transparent Conductive Film 20>

The transparent conductive film 20 is formed on the light transmissive substrate 10. When the light transmissive substrate 10 is constituted with a conductive material, the transparent conductive film 20 may not be provided. In the present embodiment, the constitution of the transparent conductive film 20 is not particularly limited, and various constitutions based on the techniques in the related art can be employed. For example, the transparent conductive film 20 may be a film formed using an electrically conductive transparent material of oxide such as ITO or FTO that is formed by sputtering or the like. In addition, in the transparent conductive film 20, carbon nanotubes or electrically conductive fibers may be sparsely dispersed to such a degree that the influence on the incident light can be minimized.

<Semiconductor Layer 30>

The semiconductor layer 30 is constituted as a porous oxide semiconductor layer, and the surface thereof adsorbs the dye 40 described below. It is desirable that the size of the pores be small in view of enlarging the area onto which the dye 40 is adsorbed, but if the size is too small, the semiconductor layer 30 obtains a property of transmitting sunlight. In consideration of this, the pore size can be set to, for example, equal to or more than 5 nm and equal to or less than 500 nm, and preferably equal to or more than 10 nm and equal to or less than 30 nm.

It is desirable that the semiconductor layer 30 have a performance of receiving electrons that are generated when the dye adsorbed onto the surface thereof absorbs light, and a performance in which the semiconductor layer 30 itself does not absorb the light of a visible region having a great irradiation intensity in the sunlight. The semiconductor layer 30 can be constituted with, for example, any of titanium oxide (TiO₂) having an energy gap of about 3 eV, niobium oxide (Nb₂O₅), zinc oxide (ZnO), and tin oxide (SnO₂), or with a mixture of these. The materials of the semiconductor layer 30 shown herein are just an example, and the present invention is not limited thereto.

The method of producing the semiconductor layer 30 is not particularly limited. For example, when the light transmissive substrate 10 is a glass substrate that has heat resistance to some degree, for producing the semiconductor layer 30, a sol solution of an oxide semiconductor or a paste including fine oxide particles and a binder is coated onto the light transmissive substrate 10, followed by baking at a temperature range of about equal to or more than 400° C. to equal to or less than 600° C., whereby the semiconductor layer 30 may be produced.

When the light transmissive substrate 10 is constituted with a plastic material or the like and does not have sufficient heat resistance, for example, a solution of a mixture of an organic metal compound and an organic polymer material is coated onto the light transmissive substrate 10, followed by ultraviolet irradiation, whereby the semiconductor layer 30 may be formed. As the organic metal compound, for example, metal alkoxide, or a metal acetylacetonato complex can be used. As the metal constituting the organic metal compound, any of Ti, Nb, Zn, and Sn, or a complex of these can be used. As the organic polymer material, polyethylene glycol or a foaming agent such as diazoaminobenzene, azodicarbonamide, or dinitroso pentamethylene tetramine can be used.

In the above method of producing the semiconductor layer 30, if the semiconductor layer 30 is formed using a solution that is obtained by further mixing particles of TiO₂ or the like having a particle size of 50 nm or more with the sol solution of the oxide semiconductor, with the paste including fine oxide particles and a binder, or with the mixed solution of the organic metal compound and the organic polymer material, the photoelectric conversion efficiency of the photoelectric conversion element can be further improved. This is because by dispersing such particles having a large particle size in the semiconductor layer 30, the light entering the electrode is scattered efficiently by the particles, and an effective optical path length is increased, whereby the probability of capturing light in the dye 40 is increased.

<Light Scattering Layer>

Though not shown in the drawing, a light scattering layer may be provided on the semiconductor layer 30. The light scattering layer is provided to return the light, which is transmitted through the semiconductor layer 30 without being absorbed by the dye 40, to the semiconductor layer 30 again. The scattering layer can be constituted with the same elements as those of the semiconductor layer 30, but the fine oxide particles used desirably include particles having a particle size of equal to or more than 50 nm and equal to or less than 1000 nm that are suitable for scattering sunlight.

<Counter Electrode 60>

In the present embodiment, the constitution of the counter electrode 60 is not particularly limited, and various constitutions based on the technique in the related art can be employed. That is, though the holes generated from the dye 40 of the semiconductor layer 30 are transported to the counter electrode 60 through the electrolyte 50, the material of the counter electrode 60 is not limited so long as the counter electrode 60 reliably performs the function of causing the electrons and holes to annihilate each other efficiently. For example, the counter electrode 60 can use a metal vapor-deposition film that is formed on a substrate by vapor deposition or the like. Specifically, a platinum layer formed on a substrate can be used. In addition, the counter electrode 60 may include a nanocarbon material. For example, the counter electrode 60 may be formed by sintering a paste including carbon nanotubes, carbon nanohorns, or carbon fibers on a porous insulating film. The nanocarbon material has a large specific surface area, and can improve the efficiency of annihilation between electrons and holes. In order to produce a light transmissive counter electrode 60, a catalytic layer of platinum, carbon, or the like is formed on a transparent conductive film-attached glass as a substrate by vapor deposition or sputtering, whereby the counter electrode 60 can be prepared.

<Dye 40>

As the dye 40 usable in the present embodiment, a dye is preferable which absorbs the light of a visible light region and an infrared light region, and has an interlock group such as a carboxyl group, an alkoxy group, a hydroxyl group, a hydroxyalkyl group, a sulfonic acid group, an ester group, a mercapto group, or a sulfonyl group in the dye molecule so as to be strongly adsorbed onto the semiconductor layer 30. A dye having a carboxyl group among these interlock groups is particularly preferable. The interlock group has a function of adsorption and a function of facilitating the movement of electrons between the excited dye 40 and a conductive band of the semiconductor layer 30.

Examples of the dye 40 usable in the present embodiment includes ruthenium metal complex dyes (such as a ruthenium bipyridine-based metal complex dye, a ruthenium terpyridine-based metal complex dye, and ruthenium quaterpyridine-based metal complex dye), azo-based dyes, quinone-based dyes, quinonimine-based dyes, quinacridone-based dyes, squarylium-based dyes, cyanine-based dyes, merocyanine-based dyes, triphenylmethane-based dyes, xanthene-based dyes, porphyrin-based dyes, phthalocyanine-based dyes, perylene-based dyes, indigo-based dyes, naphthalocyanine-based dyes, coumarin-based dyes, and the like which have an interlock group. Among these, ruthenium metal complex dyes are preferable. One kind of dye may be adsorbed, or a mixture of two or more kinds of dyes may be adsorbed.

The molecular weight of the widely used ruthenium dye is about 1100 for N719 and about 740 for D149. Among the dyes 40 usable in the present embodiment, organic dyes with a relatively small molecular weight have a molecular weight of about 400.

Examples of the method of causing the dye 40 to be adsorbed onto the semiconductor layer 30 include a method of impregnating the semiconductor layer 30 formed on the light transmissive substrate 10 with a solution in which the dye 40 is dissolved. The solvent used for dissolving the dye 40 is not particularly limited, and examples of the solvent include alcohols such as ethanol, ketones such as acetone, ethers such as diethyl ether and tetrahydrofuran, nitrogen compounds such as acetonitrile, halogenated aliphatic hydrocarbons such as chloroform, aliphatic hydrocarbons such as hexane, aromatic hydrocarbons such as benzene, esters such as ethyl acetate, and the like.

<Electrolyte 50>

The electrolyte 50 needs to have a function of transporting the holes generated by the dye 40 to the counter electrode 60, and is constituted with a redox species, a solvent, and additives.

The redox species is a radical compound generated from an organic compound, and is not particularly limited as long as it has an average molecular weight of equal to or more than 200 and less than 1000, preferably equal to or more than 200 and equal to or less than 700. The redox species is desirably a stabilized radical compound. Examples of potential radical groups include compounds having an oxyradical group, a nitroxyl radical group, a carbonate radical group, or a boron radical group. In the present embodiment, it is possible to use a radical compound including one or more of these radical groups (different radical groups may be included). When the molecular weight of the dye 40 is regarded as 1, the proportion of the average molecular weight of the radical compound is 0.3 or more, and preferably 0.5 or more, and the reason will be described below.

The radical in the electrolyte 50 is oxidized and reduced in a state of a radical and a cationic state. In order to stabilize the cationic state generated, a salt is added to the electrolyte 50. As the salt used, lithium, sodium, potassium, ammonium, imidazolium, oxazolium, triazolium, piperidinium, pyrazolium, isoxazolium, thiadiazolium, oxadiazolium, triazolium, pyrrolidinium, pyridinium, pyrimidinium, pyridazinium, pyrazinium, triazinium, phosphonium, sulfonium, carbazolium, indolium, and derivatives of these are preferable as cations. Among these, ammonium, imidazolium, pyridinium, piperidinium, pyrazolium, and sulfonium are particularly preferable. Examples of anions include fluorine-containing compounds such as PF₆⁻, BF₄⁻, CF₃SO₃⁻, N (CF₃SO₂)₂⁻, F(HF)ₙ⁻, and CF₃COO⁻, non-fluorine compounds such as NO₃⁻, CH₃COO⁻, C₆H₁₁COO⁻, CH₃OSO₃⁻, CH₃OSO₂⁻, CH₃SO_{3 f} CH₃SO₂⁻, (CH₃O)₂PO_{2hu -}, and SbCl₆⁻, halogen compounds such as bromine, and the like.

Examples of the solvent include, as organic solvents, nitrogen-containing compounds such as N-methylpyrrolidone and N,N-dimethylformamide, nitrile compounds such as methoxypropionitrile and acetonitrile, lactone compounds such as γ-butyrolactone and valerolactone, carbonate compounds such as ethylene carbonate, diethyl carbonate, dimethyl carbonate, and propylene carbonate, ethers such as tetrahydrofuran, dioxane, diethyl ether, and ethylene glycol dialkyl ether, alcohols such as methanol, ethanol, and isopropyl alcohol, imidazoles, and the like.

A gelating agent or the like can be added to the electrolyte 50 so as to make the electrolyte 50 in a pseudo-solid state. As the gelating agent, a polymeric gelating agent is preferably used. Examples thereof include polymeric gelating agents such as cross-linked polyacrylic resin derivatives, cross-linked polyacrylonitrile derivatives, polyalkylene oxide derivatives, silicone resins, and polymers having a structure of a nitrogen-containing heterocyclic quaternary compound salt on a side chain.

As other additives, nitrogen-containing heterocyclic quaternary ammonium salt compounds such as pyridinium salts and imidazolium salts may be added.

### EXAMPLES

Hereinafter, the method of producing the photoelectric conversion element of the present invention will be described in detail based on examples, but the present invention is not limited thereto.

### Example 1

<Preparation of Photoelectric Conversion Element>

<<Preparation of Semiconductor Electrode 70>>

First, the semiconductor layer 30 formed of zinc oxide (ZnO) of the photoelectric conversion element according to the present invention was prepared in the following sequence.

15 mm×10 mm of FTO-attached glass (10 Ωcm²) having a thickness of 1.1 mm was prepared. As surface treatment, a 0.005 mol/L ethanol solution of zinc acetate (manufactured by KANTO KAGAKU) was dripped onto the FTO surface, followed by rinsing with ethanol, and then the resultant was dried. This operation was repeated three times, and then the resultant was dried at 200° C. in the atmosphere.

Next, on the FTO surface having undergone surface treatment, a core-like crystal layer of zinc oxide was prepared as a material of the semiconductor layer 30. Specifically, first, a mixed solution of 0.025 mol/L zinc nitrate (manufactured by KANTO KAGAKU) and 0.025 mol/L hexamethylenetetramine (manufactured by KANTO KAGAKU) was prepared. Thereafter, at room temperature, the glass substrate was placed in the mixed solution such that the FTO surface having undergone surface treatment faced upward, and the temperature of the mixed solution was increased to 90° C. for 30 minutes and then held as is for 2 hours to precipitate core-like crystals of zinc oxide on the FTO surface, followed by washing with water.

Subsequently, this glass substrate was inserted into an electric furnace and baked at 500° C. for about 30 minutes in the atmosphere, followed by natural cooling, thereby forming a porous zinc oxide semiconductor layer formed of core-like crystals. Since the zinc oxide layer was formed on the entire FTO surface, an unnecessary portion of the zinc oxide layer was scraped off after baking such that an area having sides of 5 mm remained.

Thereafter, a dye was adsorbed onto the surface of the semiconductor layer 30 formed of the zinc oxide (ZnO). Specifically, an organic dye D149 (manufactured by MITSUBISHI PAPER MILLS LIMITED) was dissolved in a solution of “acetonitrile (manufactured by KANTO KAGAKU):tertiary butanol (manufactured by Sigma-Aldrich Co., LLC.)=1:1” at a concentration of 2×10⁻⁴M, and the glass substrate on which the semiconductor layer 30 had been formed was dipped into this dye solution for about 2 hours. Subsequently, the glass substrate was taken out of the dye solution and held in an acetonitrile solution (manufactured by KANTO KAGAKU) for 5 minutes to remove the surplus dye 40, and then dried in an oven at 80° C. for about 1 minute in the atmosphere.

<<Preparation of Counter Electrode 60>>

A platinum layer having an average film thickness of 0.3 μm was vapor-deposited onto a soda lime glass substrate (thickness of 1.1 mm) by vacuum vapor deposition, thereby preparing the counter electrode 60.

<<Cell Assembly>>

The semiconductor electrode 70 and the counter electrode 60 were arranged such that the semiconductor layer 30 and the platinum layer faced each other, and the periphery of the cell portion was thermally compressed using a thermosetting resin film in which cuts were made to make it possible for the electrolyte 50 to penetrate.

<<Injection of Electrolyte 50>>

As a redox species of the electrolyte 50, PTIO (2-phenyl-4,4,5,5-tetramethylimidazolin-1-oxyl-3-oxide:

molecular weight 233: manufactured by Wako Pure Chemical Industries, Ltd) was used. Specifically, a 0.5 mol/L ethanol solution of PTIO was prepared. As a salt solution added to the electrolyte 50, a 1 mol/L lithium bis(pentafluoroethanesulfonyl)imide (LiBETI) solution using propylene carbonate as a solvent was prepared. The ethanol solution including PTIO was mixed with the salt solution at a ratio of 5:1, thereby obtaining an electrolyte solution using a redox species as a radical. This electrolyte solution was injected into the cell portion through the cuts in the thermosetting resin film.

<Photocurrent Measurement>

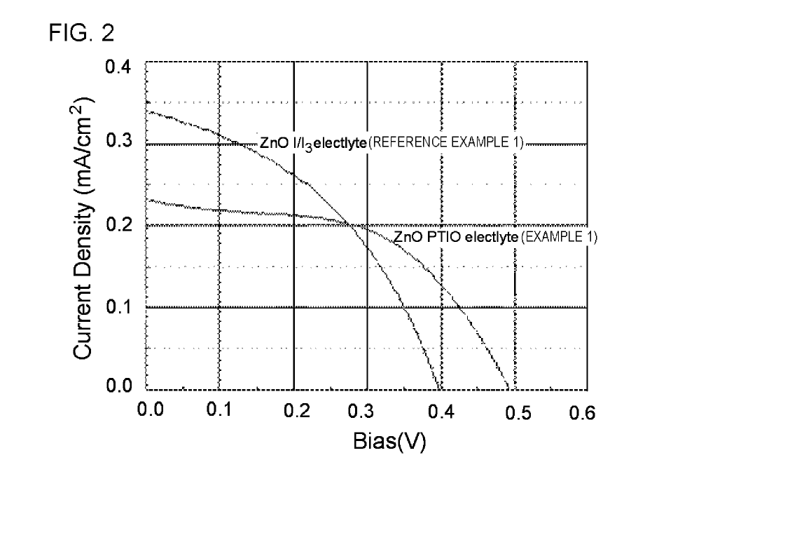

The photoelectric conversion element prepared as above was irradiated with light having an intensity of 100 mW/cm² under a condition of AM 1.5 by using a solar simulator, and the generated electricity was measured using a current and voltage-measuring instrument, thereby evaluating photoelectric conversion characteristics. The results are shown in FIG. 2. As shown in the drawing, a closed-circuit current of 0.23 mA/cm² and an open-circuit voltage of 0.49 V could be observed.

### Reference Example 1

<Preparation of Photoelectric Conversion Element>

A photoelectric conversion element was prepared by the same sequence as in Example 1, except that an iodine-based electrolyte was used as an electrolyte.

As an electrolyte solution, a solution was used which used methoxypropionitrile as a solvent and was adjusted such that the iodine had a concentration of 0.5 mol/L, lithium iodide had a concentration of 0.1 mol/L, 4-tert-butylpyridine had a concentration of 0.5 mol/L, and 1,2-dimethyl-3-propylimidazolium iodide had a concentration of 0.6 mol/L.

<Photocurrent Measurement>

The photoelectric conversion element prepared as above was irradiated with light having an intensity of 100 mW/cm² under a condition of AM 1.5 by using a solar simulator, and the generated electricity was measured using a current and voltage-measuring instrument, thereby evaluating photoelectric conversion characteristics. The results are shown in FIG. 2. As shown in the drawing, a closed-circuit current of 0.32 mA/cm² and an open-circuit voltage of 0.4 V could be observed.

The above results demonstrated that from the constitution of the present invention shown in Example 1, performances equivalent to those of the photoelectric conversion element using the iodine electrolyte of the related art shown in the reference example were obtained.

The size of the gaps in the dye 40 that is in a state of being sufficiently adsorbed onto the semiconductor layer 30 is considered to be influenced by the size of the dye 40, that is, by the molecular weight of the dye 40. Specifically, the greater the molecular weight of the dye 40, the larger the gaps in the dye 40 in a state of being sufficiently adsorbed. Inversely, it is considered that the smaller the molecular weight of the dye 40, the smaller the gaps in the dye 40 in a state of being sufficiently adsorbed.

In Example 1, the organic dye D149 having a molecular weight of 740 was used as the dye 40, and PTIO having a molecular weight of 233 was used as a radical compound, whereby performances equivalent to those of the photoelectric conversion element using the iodine electrolyte of the related art were realized. It is considered that this is because tertiary-butylpyridine was not added to the electrolyte, and the radical compound was inhibited from entering the gaps in the dye, hence the recombination of charge caused on the semiconductor layer 30 by the radical compound could be inhibited. That is, it is considered that when the molecular weight of the dye 40 is regarded as 1, if the proportion of the average molecular weight of the radical compound is about 0.3 or more, the recombination of charge caused on the semiconductor layer 30 by the radical compound can be inhibited.

As described above, it was understood that when the molecular weight of the dye 40 is regarded as 1, if the proportion of the average molecular weight of the radical compound is about 0.3 or more, the recombination of charge caused on the semiconductor electrode by the radical compound can be inhibited, and consequently, performances equivalent to those of the photoelectric conversion element using the iodine electrolyte of the related art can be realized. In this case, it is considered that when the molecular weight of the dye 40 is regarded as 1, if the proportion of the average molecular weight of the radical compound is about 0.5 or more, the recombination of charge caused on the semiconductor layer 30 by the radical compound can be more reliably inhibited, and a sufficient photoelectric conversion efficiency can be realized.

### Example 2

<Preparation of Photoelectric Conversion Element>

<<Preparation of Semiconductor Electrode 70>>

The semiconductor electrode 70 was prepared in the same manner as in Example 1, except that the semiconductor layer 30 was prepared using titanium oxide (TiO₂). The semiconductor layer 30 was prepared in the following manner.

15 mm×10 mm of FTO-attached glass (10 Ωcm²) having a thickness of 1.1 mm was prepared. The FTO surface was washed with ethanol and isopropanol and then dried at 200° C. in the atmosphere.

As a solvent, 20 ml of an aqueous acetic acid solution having a concentration of 15 vol % was used, and 5 g of commercially available porous titanium oxide powder (P25, NIPPON AEROSIL CO., LTD), 0.1 mL of a surfactant (Triton OX-100, Sigma-Aldrich Co., LLC.) , and 0.3 g of polyethylene glycol (molecular weight 20000) were added thereto, followed by stirring with a stirring mixer for about an hour (6 times of stirring, 10 minutes per stirring), thereby preparing a titanium oxide paste.

Thereafter, the titanium oxide paste was coated (coated area: 5 mm×5 mm) in an appropriate amount onto the washed FTO-attached glass by screen printing so as to yield a film thickness of about 20 μm. This electrode was inserted into an electric furnace so as to be baked at 450° C. for about 30 minutes in the atmosphere, thereby obtaining a titanium oxide semiconductor layer.

<<Preparation of Counter Electrode 60>>

The counter electrode 60 was prepared in the same manner as in Example 1.

<<Cell Assembly>>

Cell assembly was performed in the same manner as in Example 1.

<<Injection of Electrolyte 50>>

As a radical compound of an electrolyte, 4-acetamide-TEMPO manufactured by Sigma-Aldrich Co., LLC. (molecular weight=213) was used. As an electrolyte solution, a solution obtained by blending 0.1 mol/L 4-acetamide-TEMPO with 1.2 mol/L LiTFSI, and 0.01 mol/L NOBF₄ was used. Other conditions were the same as in Example 1.

<Photocurrent Measurement>

Photocurrent was measured in the same manner as in Example 1, and as a result, a closed-circuit current of 2.1 mA/cm² and an open-circuit voltage of 0.68 V were obtained.

### Example 3

<Preparation of Photoelectric Conversion Element>

As a radical compound of an electrolyte, PTIO (2-phenyl-4,4,5,5-tetramethylimidazolin-1-oxyl-3-oxide: manufactured by Wako Pure Chemical Industries, Ltd (molecular weight=233)) was used. As an electrolyte solution, a solution obtained by blending 0.1 mol/L 4-acetamide-TEMPO with 1.2 mol/LLiTFSI, and 0.01 mol/L NOBF₄ was used. Other conditions were the same as in Example 2.

<Photocurrent Measurement>

Photocurrent was measured in the same manner as in Example 1, and as a result, a closed-circuit current of 2.3 mA/cm² and an open-circuit voltage of 0.71 V were obtained.

### Example 4

<Preparation of Photoelectric Conversion Element>

As a radical compound of an electrolyte, 2,2-diphenyl-1-picrylhydrazyl manufactured by Sigma-Aldrich Co., LLC. (molecular weight=394) was used. As an electrolyte solution, a solution obtained by blending 0.1 mol/L 2,2-diphenyl-1-picrylhydrazyl with 1.2 mol/L LiTFSI, and 0.01 mol/L NOBF₄ was used. Other conditions were the same as in Example 2.

<Photocurrent Measurement>

Photocurrent was measured in the same manner as in Example 1, and as a result, a closed-circuit current of 1.3 mA/cm² and an open-circuit voltage of 0.69 V were obtained.

### Example 5

<Preparation of Photoelectric Conversion Element>

As a radical compound of an electrolyte, galvinoxyl free radical (molecular weight=422) was used. As an electrolyte solution, a solution obtained by blending 0.1 mol/L galvinoxyl free radicals with 1.2 mol/L LiTFSI, and 0.01 mol/L NOBF₄ was used. Other conditions were the same as in Example 2.

<Photocurrent Measurement>

Photocurrent was measured in the same manner as in Example 1, and as a result, a closed-circuit current of 1.1 mA/cm² and an open-circuit voltage of 0.70 V were obtained.

### Comparative Example 1

<Preparation of Photoelectric Conversion Element>

As a radical species added to an electrolyte solution, TEMPO (2,2,6,6-tetramethylpiperidine-1-oxyl manufactured by Wako Pure Chemical Industries, Ltd. (molecular weight=156)) was used. As an electrolyte solution, a solution obtained by blending 0.1 mol/L TEMPO with 1.2 mol/L lithium bis(trifluoromethanesulfonyl)imide (LiTFSI), and 0.01 mol/L nitrosyl tetrafluoroborate (NOBF₄) was used. Other conditions were the same as in Example 2.

<Photocurrent Measurement>

Photocurrent was measured in the same manner as in Example 1, and as a result, a closed-circuit current of 1.7 mA/cm² and an open-circuit voltage of 0.4 V were obtained.

### Comparative Example 2

<Preparation of Photoelectric Conversion Element>

As a radical species of an electrolyte, PTMA (molecular weight=89000) was used. The semiconductor layer 30 was prepared using titanium oxide (TiO₂) just like Example 2. The cell structure was the same as in Example 1. An electrolyte was coated onto a semiconductor electrode, acetonitrile was dripped thereonto to blend the electrolyte with the semiconductor electrolyte, and a counter electrode was bonded thereto, thereby preparing a cell. Other conditions were the same as in Example 2.

<Photocurrent Measurement>

Photocurrent was measured in the same manner as in Example 1, and as a result, a closed-circuit current of 0.02 mA/cm² and an open-circuit voltage of 0.54 V were obtained.

The results of photocurrent measurement of Examples 2 to 5 and Comparative Examples 1 and 2 are summarized in Table 1. From Table 1, it is understood that when the molecular weight of the radical compound is equal to or more than 200 and less than 1000 (Examples 2 to 5), the value of photocurrent or the open-circuit voltage is increased, compared to the case where the molecular weight of the radical compound is less than 200 (Comparative Example 1) and 1000 or more (Comparative Example 2). Particularly, it is considered that the radical compound having a molecular weight of 200 or more can be inhibited from entering the gaps in the dye, and consequently, the recombination of charge caused on the semiconductor layer by the radical compound can be inhibited.

TABLE 1

| | Closed-circuit current | Open-circuit voltage |
|---|---|---|
| | (mA/cm²) | (V) |
| Example 2 | 2.1 | 0.68 |
| Example 3 | 2.3 | 0.71 |
| Example 4 | 1.3 | 0.69 |
| Example 5 | 1.1 | 0.70 |
| Comparative | 1.7 | 0.40 |
| Example 1 | | |
| Comparative | 0.02 | 0.54 |
| Example 2 | | |

By using the photoelectric conversion element of the present embodiment for a photosensor and a solar cell based on the technique in the related art, it is possible to provide a photosensor and a solar cell that are excellent in practical use.

The present application claims priority based on Japanese Patent Application No. 2010-067282 filed Mar. 24, 2010, the entire content of which is incorporated herein.

1. A photoelectric conversion element comprising:
a semiconductor electrode that has a porous semiconductor layer onto which a dye is adsorbed;
a counter electrode that is provided so as to face the semiconductor layer of the semiconductor electrode; and
an electrolyte that contains a radical compound having an average molecular weight of 200 or more and is positioned between the semiconductor electrode and the counter electrode, wherein the dye is an organic dye D149.

2. The photoelectric conversion element according to claim 1,
wherein the radical compound includes 4-acetamide-TEMPO.

3. The photoelectric conversion element according to claim 1,
wherein the radical compound includes 2-phenyl-4,4,5,5-tetramethylimidazolin-1-oxyl-3-oxide.

4. The photoelectric conversion element according to claim 1,
wherein the radical compound includes a galvinoxyl free radical.

5. The photoelectric conversion element according to claim 1,
wherein a pore diameter of the semiconductor layer is equal to or more than 5 nm and equal to or less than 500 nm.

6. The photoelectric conversion element according to claim 1,
wherein when the molecular weight of the dye is regarded as 1, the proportion of the molecular weight of the radical compound is 0.3 or more.

7. The photoelectric conversion element according to claim 1,
wherein the semiconductor layer includes zinc oxide.

8. The photoelectric conversion element according to claim 1,
wherein the radical compound contained in the electrolyte has an average molecular weight of less than 1000.

9. A photosensor comprising the photoelectric conversion element according to claim 1.

10. A solar cell comprising the photoelectric conversion element according to claim 1.
